(19) United States
(12) Patent Application Publication
(10) Pub. No.: US 2008/0148972 A1
(43) Pub. Date: Jun. 26, 2008

(54) Low-wear bearer ring

(75) Inventors: Rainer Endes, Karsbach (DE); Peter Schmitt, Wurzburg (DE)

Correspondence Address: K.F. ROSS P.C., 5683 RIVERDALE AVENUE, SUITE 203 BOX 900, BRONX, NY, 10471-0900, US

(73) Assignee: KBA-METRONIC AG

(21) Appl. No.: 12/002,942

(22) Filed: Dec. 19, 2007

(30) Foreign Application Priority Data
Dec. 22, 2006 (DE) 102006062282.0

(51) Int. Cl. B41F 13/21; C23C 16/00; B21K 1/02

(52) U.S. Cl. 101/216; 118/715; 29/895.32

(57) ABSTRACT

A printing roller carries a bearer ring comprised of a metallic body having an outer surface, and a hard, chemically inert, electrically insulating, and diamond-like layer on the outer surface. This ring is used with lubrication and is made by fitting a ring without a coating to a roller, machining it true on the roller, then removing it from the roller and coating its surface with a DLC layer, and finally reinstalling it on the printing roller.

### FIELD OF THE INVENTION

The present invention relates to a bearer or Schmitz ring. More particularly this invention concerns a method of reducing wear of such a ring and a method of using such a ring.

### BACKGROUND OF THE INVENTION

It is standard to provide the cylindrical rollers of printing machines with so-called Schmitz or bearer rings. These rings are normally mounted at the ends of the printing rollers and bear radially on each other so as to both accurately space the surfaces of the rollers from each other and to also transmit torque from one roller to the other so they rotate perfectly synchronously. Such bearer rings thus replace the extraordinarily accurate bearing mounts and drives that such printing rollers otherwise require to work properly.

Use of such bearer rings reduces stress in the printing rollers, since the stress is concentrated in the bearer rings. In order to withstand the high mechanical stresses, high-strength and hard steels are used for the bearer rings, and the surfaces of the bearer rings, particularly the outer running surfaces thereof, are in part additionally hardened. In addition, during operation, the running surfaces are lubricated, since otherwise rolling friction and the constant contamination due to dust, printing ink, and the like would cause wear and result in only a short service life of the bearer rings.

It has been found, however, that even when using special lubricants the bearer rings wear after a short time. This wear results, for example, in abrasion, scoring, and rust particles that cause worsened rolling properties and therefore a worse printed image. Another source of wear of the bearer rings is corrosion due to electric current, whereby due to the different materials of the bearer rings rolling on each other an electric current flows between the materials in the contact zone, which may electrochemically decompose ink or similar contamination located in this zone.

This may produce reactive side products that in turn corrode the material of the bearer rings and damage them over time. For this reason, special lubricants are required that have high chemical resistance, low reactivity, and a high dielectric constant, in order to effectively counteract this risk. In addition, there is a risk of contaminating the printing machine or the printing rollers or the print substrate with the lubricants, which also carry particles or rust, or by abrasion as such. Furthermore, the surfaces of conventional bearer rings are not inert with regard to other chemical influences, so that they can likewise be damaged, for example under the effects of cleaning agents or ozone that are also produced in part by drying systems.

### OBJECTS OF THE INVENTION

It is therefore an object of the present invention to provide an improved low-wear bearer ring.

Another object is the provision of such an improved low-wear bearer ring, a method of making such a ring, and a method of using such a ring.

A further object is to provide a bearer ring that overcomes the above-given disadvantages, in particular that resists wear and that generally avoids the above-given disadvantages of the known bearer rings, so as to increase the service life of the bearer rings and reduce their rolling friction relative to one another and so that the use of lubricants can be reduced or additional lubricant can be foregone altogether, all while protecting the bearer rings from chemical influences. A further object is to maintain the print image in printing machines at an optimum level over a long period.

### SUMMARY OF THE INVENTION

In combination with a printing roller, a bearer ring comprised of

a metallic body having an outer surface, and a hard, chemically inert, electrically insulating, and diamond-like layer on the outer surface.

The object is thus is achieved in that the surface of the inventive bearer rings, particularly the outer surface serving as running surface, is provided with a protective layer, particularly a hard layer. The bearer rings, preferably pairs of bearer rings, which subsequently during normal operation roll on each other, are provided with a wear-reducing protective layer at least on the outer rolling surface, particularly with the diamond-like layer.

By applying a separate layer on a bearer ring, it is possible to ideally select this separate layer with respect to the properties thereof and match it to the requirements, which is clearly different from just treating—e.g. nitriding—the surface to change its properties without significantly changing its composition. The optimization efforts of the prior art were therefore always limited to the properties that could be achieved with the bearer ring material.

According to the invention, preferably a material is selected that has greater hardness than the remaining material of the bearer ring, thus considerably lowering wear. It may also be provided that a material is selected that is chemically inert and/or electrically insulating. In this way, local decomposition processes, for example contact potentials, can be avoided. Preferably a material is selected that combines all these properties, for example a diamond-like layer or even diamond, particularly synthetic industrial diamond, for example in that such a material is grown on the running surface of a bearer ring.

Diamond-like layers have a number of excellent properties. Despite their graphite-like internal structure, they have diamond-like properties, for example in that during the deposition of the layers, which is performed for example by means of a CVD (Chemical Vapor Deposition) method, the carbon present in the process on the surface of the component to be coated is precipitated locally at least partially in a diamond lattice.

The resulting coating thus comprises at least in partial regions polycrystalline and/or amorphous diamond. In addition a superlattice is produced that, viewed across a macroscopic range, has at least partially a graphite-like structure. Layers of this type are generally abbreviated as DLC (Diamond Like Coating).

The mechanical, chemical, thermal, electrical and optical properties of such a DLC are in part very similar to true diamond. DLC layers therefore have a microhardness value of approximately 1,500 to 3,000 kp/mm² and are considerably harder than highly hardened steels, in addition they have a very low friction coefficient of approximately 0.1 relative to steel or less than 0.02 relative to another DLC layer, and depending on the configuration of the DLC layer they have antiadhesive properties resembling those of polytetrafluoroethylene (PTFE).

In addition, such DLC layers are chemically resistant toward a variety of corrosive media, such as acids, lyes, solvents and the like and protect a bearer ring coated with a DLC effectively against corrosion.

According to the invention, a preferred embodiment may be that the bearer rings are coated with a DLC layer having a thickness ranging between 0.5 μm and 5 μm, preferably having a layer thickness ranging between 1 μm and 3 μm, particularly since it has been shown that DLC layers at these thicknesses not only have a high protective effect, but are also still flexible enough to follow the dynamic deformations of the bearer rings like those occurring during rolling when the printing rollers are in use.

### BRIEF DESCRIPTION OF THE DRAWING

The above and other objects, features, and advantages will become more readily apparent from the following description, reference being made to the accompanying drawing in which:

FIG. 1 is a large-scale section through a bearer ring according to the invention;

FIG. 2 is a partly sectional side view of a printing machine with the bearer rings in accordance with the invention; and

FIGS. 3a-3c are schematic view illustrating the main steps in making the assembly according to the invention.

### SPECIFIC DESCRIPTION

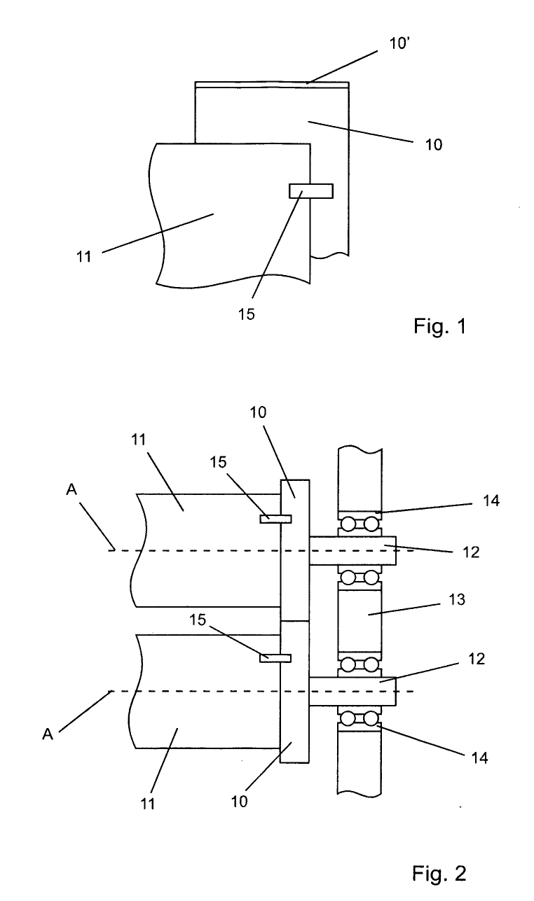

As seen in FIG. 1 a cylindrically annular ring 10 of steel is provided on its cylindrical outer surface with a coating 10′ of DLC material. FIG. 2 shows how two of these rings 10 are mounted on the ends of rollers 11 having central stub shafts 12 set in bearings 14 of a stand 13 for rotation about parallel axes. The rings 10 are held in place by radial pins 15 (FIG. 1) engaged in them and in the rollers 11.

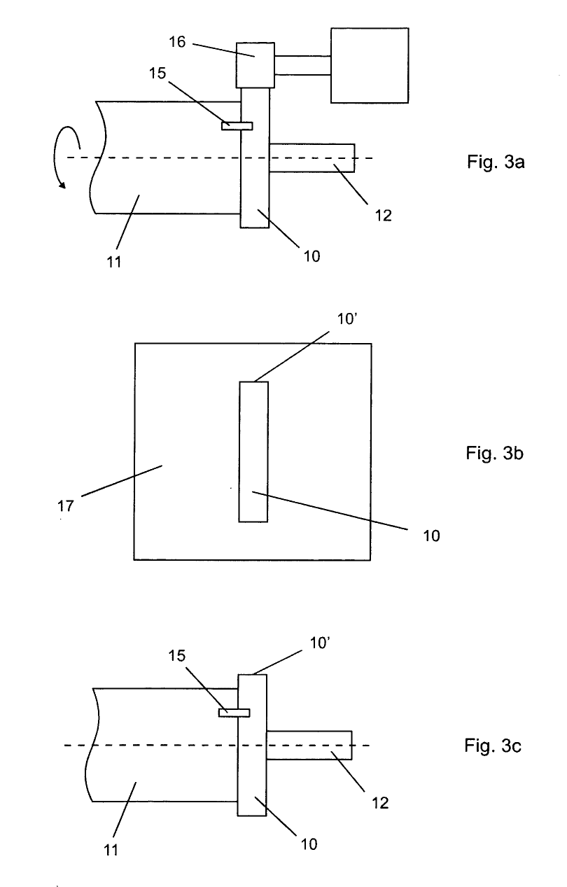

FIG. 3a illustrates how, for reducing wear of the bearer rings, they are produced in the conventional manner of steel, without the layer 10′, and mounted on the appropriate rollers 11. After the assembly process, entire assembly of roller 11 and ring 10 is machined together by truing, turning, grinding, or polishing, or the like. Here a grinding stone 16 is shown. By doing this right on the roller 11, the ring 10 is machined to be perfectly true.

Then as shown in FIG. 3b, the ring 10 is taken off the roller 11 and put in a diagrammatically illustrated autoclave where it is subjected to vacuum and a CVD deposition process that forms the DLC layer on the outer face of the ring 10.

Thereafter as shown in FIG. 3c the coated ring 10 with the layer 10′ is reinstalled on the roller 11. Pins 15 (FIG. 1) are used to secure the ring 10 solidly in place on the roller 11.

The printing roller produced in this way, in particular the outer surface of the bearer rings can be cleaned after the machining step shown in FIG. 3a and before the coating step shown in FIG. 3b, in order to guarantee maximum adhesion of the layer, particularly the DLC coating. This cleaning can be done in the conventional manner, for example with the use of solvents, dry ice, ultrasonic baths or the like.

The CVD method is a plasma-supported chemical deposition method from the gaseous phase, the layer being made of a noble gas-methane plasma that is directly applied to the surface to be coated. The operating temperatures may be in the range from 100° to 800° C., where for the coating of the rollers preferably a low temperature range of 100° C. to 200° C. is selected in order to minimize thermal influence on the bearer rings. The printing roller provided with such a layer, particularly a DLC layer, on the bearer rings can then be used without additional lubrication inside the printing couple.

Preferably only a small vacuum chamber 17 is used for coating. This chamber 17 can CVD coat the outer surfaces of plurality of bearer rings 10 at the same time, thus making the coating step more cost-efficient. The bearer rings 10 coated in this way are subsequently mounted back on the printing rollers 11 in the previously defined position and layout, that is they are put back onto the ends of the rollers they are taken off.

We claim:

1. In combination with a printing roller, a bearer ring comprised of
a metallic body having an outer surface; and
a hard, chemically inert, electrically insulating, and diamond-like layer on the outer surface.

2. The combination defined in claim 1 wherein the layer is harder than the body.

3. The combination defined in claim 1 wherein the layer has a thickness of 0.5 μm to 5 μm.

4. The combination defined in claim 3 wherein the layer has a thickness of 1 μm to 3 μm.

5. The combination defined in claim 1 wherein the layer is such that when rolled on another such layer the layers have a rolling friction resistance value in the range of 0.01 to 0.5 relative to each other.

6. The combination defined in claim 1 wherein the layer has a surface tension in the range of 14 mN/m to 24 mN/m.

7. A method of using the bearer ring and cylinder according to claim 1 in a system with two such cylinders with bearer rings bearing directly on each other, the method comprising;
maintaining an interface between the bearer rings free of lubricant.

8. A method of reducing the wear of bearer rings carried on parallel printing cylinders and bearing radially on each other, the method comprising the step of:
providing each of the bearer rings with a protective, chemically inert, electrically insulating, wear-reducing diamond-like layer at least on their outer surfaces.

9. The method defined in claim 8, further comprising the steps of:
fitting the rings to the rollers and thereafter providing them with the protective layers.

10. The method defined in claim 9, further comprising the step of:
machining the rings after fitting them to the rollers and before providing them with the protective layers.

11. The method defined in claim 10 wherein the rings are machined by turning, grinding, polishing or cleaning.

12. The method defined in claim 10 wherein the ring is machined while on the respective roller, the method further comprising the step of
removing the ring from the roller before providing it with the protective layer; and
thereafter remounting the ring on the roller.

13. The method defined in claim 8, further comprising the step of
fixing the ring with pins to the roller.

14. The method defined in claim 8 wherein the layer is applied to the ring by a CVD method in a vacuum.
